(19) United States
(12) Patent Application Publication
(10) Pub. No.: US 2018/0190716 A1
(43) Pub. Date: Jul. 5, 2018

(54) Three-Dimensional Vertical Multiple-Time-Programmable Memory Comprising No Separate Diode Layer

(71) Applicant: Guobiao ZHANG, Corvallis, OR (US)

(72) Inventor: Guobiao ZHANG, Corvallis, OR (US)

(73) Assignee: ChengDu HaiCun IP Technology LLC, ChengDu (CN)

(21) Appl. No.: 15/911,112

(22) Filed: Mar. 3, 2018

Related U.S. Application Data
(63) Continuation-in-part of application No. 15/488,489, filed on Apr. 16, 2017.

(30) Foreign Application Priority Data
Apr. 16, 2016 (CN) 201610234999.5
Jan. 17, 2018 (CN) 201810046412.7
Jan. 25, 2018 (CN) 201810072214.8

(51) Int. Cl. H01L 27/24; H01L 45/00; H01L 23/528; G11C 13/00

(52) U.S. Cl. CPC H01L 27/2454; H01L 45/06; G11C 13/004; H01L 23/528; H01L 45/08

(57) ABSTRACT

The present invention discloses a three-dimensional vertical multiple-time-programmable memory (3D-MTP_{V}) comprising no separate diode layer. It comprises a plurality of vertically stacked horizontal address lines, at least a memory hole through the horizontal address lines, a memory layer and a vertical address line disposed in the memory hole. The memory layer comprises a re-programmable layer but no separate diode layer. The memory layer is leaky, i.e. its reverse current is comparable to its forward current. Sense amplifiers and a full-read mode are used to ensure a properly working 3D-MTP_{V}.

### CROSS-REFERENCE TO RELATED APPLICATIONS

This application is a continuation-in-part of “Three-Dimensional Vertical One-Time-Programmable Memory”, application Ser. No. 15/488,489, filed on Apr. 16, 2017, which claims priority from Chinese Patent Application 201610234999.5, filed on Apr. 16, 2016, in the State Intellectual Property Office of the People's Republic of China (CN), the disclosure of which is incorporated herein by reference in its entirety.

This application also claims priority from Chinese Patent Application 201810046412.7, filed on Jan. 17, 2018; Chinese Patent Application 201810072214.8, filed on Jan. 25, 2018; in the State Intellectual Property Office of the People's Republic of China (CN), the disclosure of which are incorporated herein by references in their entireties.

### BACKGROUND

### 1. Technical Field of the Invention

The present invention relates to the field of integrated circuit, and more particularly to multiple-time-programmable memory (MTP, also known as re-programmable memory).

### 2. Prior Art

Three-dimensional (3-D) multiple-time-programmable memory (3D-MTP, also known as 3-D re-programmable memory) is a monolithic semiconductor memory. It comprises a plurality of vertically stacked MTP cells. In a conventional MTP, the MTP cells are formed on a two-dimensional (2-D) plane (i.e. on a semiconductor substrate). In contrast, the MTP cells of the 3D-MTP are formed in a three-dimensional (3-D) space. The 3D-OPT has a large storage density and a low storage cost.

U.S. patent application Ser. No. 15/360,895 (Pub. No. 2017/0148851 A1) filed by Hsu on Nov. 23, 2016 discloses a 3-D vertical MTP. It comprises a plurality of horizontal address lines vertically stacked above each other, a plurality of memory holes penetrating the horizontal address lines, a re-programmable layer and a selector layer covering the sidewall of each memory hole, and a plurality of vertical address lines formed in the memory holes. The 3-D vertical MTP of Hsu uses a cross-point array. The memory cells are two-terminal devices formed at the intersections of the horizontal and vertical address lines. In order to minimize cross-talk between memory cells, each memory cell of Hsu comprises a separate selector (as will be disclosed below, selector is also referred to as diode) layer. A good-quality diode layer is generally thick. For example, a P—N thin-film diode with a good rectifying ratio is at least 100 nm thick. To form a diode layer with such a thickness in the memory hole, the diameter of the memory hole has to be large (e.g. >200 nm). This leads to a lower storage density.

In the previous patent and technical publications, selector (or, selector layer) is also referred to as diode (or, diode layer), steering element, quasi-conduction layer, or similar names. All of them belong to a broad class of diode-like devices whose resistance at the read voltage (i.e. the read resistance) is substantially lower than that when the applied voltage has a magnitude smaller than or a polarity opposite to that of the read voltage. Throughout this specification, the term “diode” is used to represent this class of devices and it is equivalent to selector, steering element, quasi-conduction layer, or similar names used in the previous patent and technical publications.

### Objects and Advantages

It is a principle object of the present invention to improve the storage density of the 3-D vertical MTP.

It is a further object of the present invention to minimize the size of the memory holes.

It is a further object of the present invention to simplify the manufacturing process inside the memory holes.

It is a further object of the present invention to provide a properly working 3-D vertical MTP even with a leaky memory layer.

In accordance with these and other objects of the present invention, the present invention discloses a three-dimensional vertical multiple-time-programmable memory (3D-MTP_{V}) comprising no separate diode layer.

### SUMMARY OF THE INVENTION

The present invention discloses a three-dimensional vertical multiple-time-programmable memory (3D-MTP_{V}) comprising no separate diode layer. It comprises a plurality of vertical MTP strings disposed side-by-side on the substrate circuit. Each MTP string is vertical to the substrate and comprises a plurality of vertically stacked MTP cells. During manufacturing, multiple layers of first conductive material (i.e. first conductive layers) are formed on the substrate circuit and they are vertically stacked above one another. These first conductive layers are etched together to form horizontal address lines. After etching a plurality of memory holes through the horizontal address lines, a memory layer is deposited to cover the sidewalls of the memory holes. Then a second conductive material is deposited into the remaining space of the memory holes. The second conductive material in each memory hole forms a vertical address line. The MTP cells are two-terminal devices formed at the intersections of the horizontal and vertical address lines. Depending on the MTP array configuration, the horizontal address lines could be word lines while the vertical address lines are bit lines; alternatively, the horizontal address lines could be bit lines while the vertical address lines are word lines.

The memory layer comprises at least a non-conductive material (which could be an insulating material or a lightly-doped semiconductor material) disposed between first and second conductive materials. Different from prior art, the preferred memory layer of the present invention comprises a re-programmable layer but no separate diode layer. The re-programmable layer generally comprises an insulating material (or, a lightly-doped semiconductor material). Its resistance can be switched from low to high and vice versa. Exemplary re-programmable layers include resistive RAM (RRAM) and phase-change memory (PCM) layers.

Without a separate diode layer, the memory layer could have a large reverse leakage current. Leaky memory layer has a detrimental effect on the read operation of a cross-point array. For a conventional read configuration, the word line associated with a selected MTP cell is biased at the read voltage Vᵣ, with other word lines biased at 0; whereas, the bit line associated with the selected MTP cell is biased at 0, with other bit lines biased at the read voltage Vᵣ. Because many MTP cells in the cross-point array are reversely biased with a large reverse bias V_{R}=−Vᵣ, the conventional read configuration is a large-V_{R} configuration. For the large-V_{R} configuration, because the reverse leakage current is too large, the read operation is error-prone and therefore, not robust.

For the MTP array to work properly, the I-V characteristic of the memory layer needs to satisfy the following current requirement: the forward current I_{F} through the selected MTP cell should be substantially larger than the collective reverse current I_{R} through all unselected MTP cells on the same bit line. This can be expressed as I_{F}>>(n−1)*I_{R}, or, I_{R}<<I_{F}/(n−1), where n is the number of MTP cells on the bit line. As n typically has a large value (˜1000), I_{R} should be significantly smaller than I_{F}, i.e. I_{R}<<I_{F}/1000. When the above current requirement is met, the reverse (leakage) current I_{R} would not interfere with the read operation.

To satisfy the above current requirement, a small-V_{R} configuration is preferred. For the small-V_{R} configuration, the largest value of the reverse bias V_{R} on the MTP cells during read is substantially smaller than the smallest value of the forward bias V_{F} on the MTP cells during read, i.e. |V_{R}|<<V_{F}. Because the forward voltage V_{F} is comparable to the read voltage Vᵣ, the value of the reverse voltage V_{R} should be substantially smaller than the read voltage Vᵣ, i.e. |V_{R}|<<Vᵣ. This is substantially smaller than the conventional large-V_{R} configuration, where |V_{R}|˜Vᵣ.

To realize the small-V_{R} configuration, the MTP array preferably comprises at least a sense amplifier, which can limit the voltage swing on the bit lines. Each sense amplifier is coupled to at least a bit line. It toggles when the voltage change on the associated bit line reaches its threshold voltage Vₜ. Because the sense amplifier typically has a large amplifying ratio, Vₜ is generally small (˜0.1V or smaller). This value is much smaller than Vᵣ (several volts), i.e. Vₜ<<Vᵣ. As a result, the bit lines have a small voltage swing during read.

In addition to sense amplifiers, a full-read mode also helps to realize the small-V_{R} configuration. For the full-read mode, the data stored in all MTP cells on a selected word line are read out during a single read cycle. The read cycle includes two read phases: a pre-charge phase and a read-out phase. During the pre-charge phase, all address lines (including all word and all bit lines) in an MTP array are pre-charged to an initial voltage Vᵢ. During the read-out phase, all bit lines are floating; a selected word line is charged to Vᵣ, while all unselected word lines remain at Vᵢ. Then the selected word line starts to charge all bit lines through the MTP cells. The sense amplifiers monitor the voltage change on the bit lines. Once the voltage change reaches Vₜ, the sense amplifier toggles and data is read out. After the data from all MTP cells are read, the read-out phase ends.

The small-V_{R} configuration can satisfy the above current requirement because the I-V characteristics of the memory layer, which comprises at least a non-conductive material, have a logarithmic curve or a nearly logarithmic curve. In a worst scenario, the memory layer has no rectifying effect, i.e. it has symmetric forward I-V curve and reverse I-V curve. Since V_{F} (several volts)>>V_{R} (˜0.1 V or smaller), the forward current I_{F} would be several orders of magnitude larger than the reverse current I_{R} because of the logarithmic I-V characteristics. Apparently, if the memory layer has certain rectifying effect, i.e. the forward I-V curve is higher than the reverse I-V curve, the forward current I_{F} would be even larger than the reverse current I_{R} and therefore, it would be even easier to meet the above current requirement.

Accordingly, the present invention discloses a three-dimensional vertical multiple-time-programmable memory (3D-MTP_{V}), comprising: a semiconductor substrate comprising a substrate circuit; a plurality of vertically stacked horizontal address lines above said semiconductor circuit; a plurality of memory holes through said horizontal address lines; a memory layer on the sidewalls of said memory holes and in contact with said horizontal address lines; a plurality of vertical address lines in said memory holes and in contact with said memory layer; a plurality of MTP cells at the intersections of said horizontal and vertical address lines; wherein said memory layer comprises a re-programmable layer but no separate diode layer.

### BRIEF DESCRIPTION OF THE DRAWINGS

FIG. 1A is a z-x cross-sectional view of a first preferred 3D-MTP_{V}; FIG. 1B is its x-y cross-sectional view along the cutline AA′; FIG. 1C is a z-x cross-sectional view of a preferred MTP cell;

FIGS. 2A-2C are cross-sectional views of the first preferred 3D-MTP_{V} at three manufacturing steps;

FIG. 3A is a symbol of the MTP cell; FIG. 3B is a circuit diagram of a first preferred read-out circuit for an MTP array; FIG. 3C is its signal timing diagram; FIG. 3D shows the current-voltage (I-V) characteristic of a preferred memory layer;

FIG. 4A is a z-x cross-sectional view of a second preferred 3D-MTP_{V}; FIG. 4B is its x-y cross-sectional view along the cutline BB′; FIG. 4C is a circuit diagram of a second preferred read-out circuit for an MTP array.

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments. The symbol “/” means a relationship of “and” or “or”.

Throughout the present invention, the phrase “on the substrate” means the active elements of a circuit are formed on the surface of the substrate, although the interconnects between these active elements are formed above the substrate and do not touch the substrate; the phrase “above the substrate” means the active elements are formed above the substrate and do not touch the substrate.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

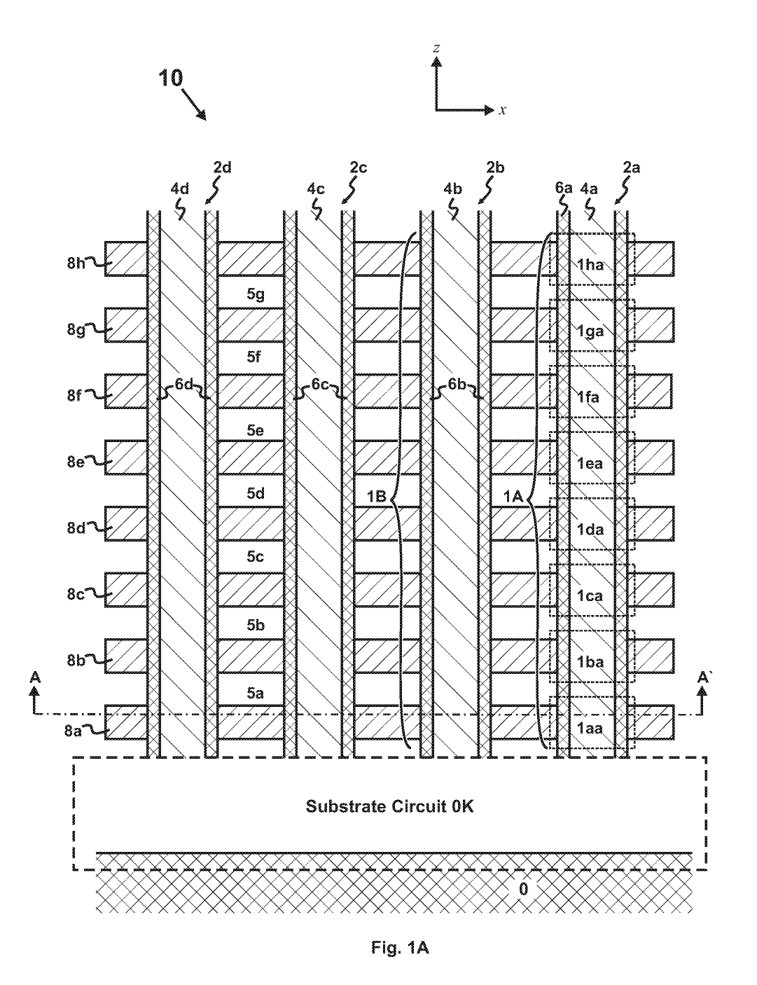

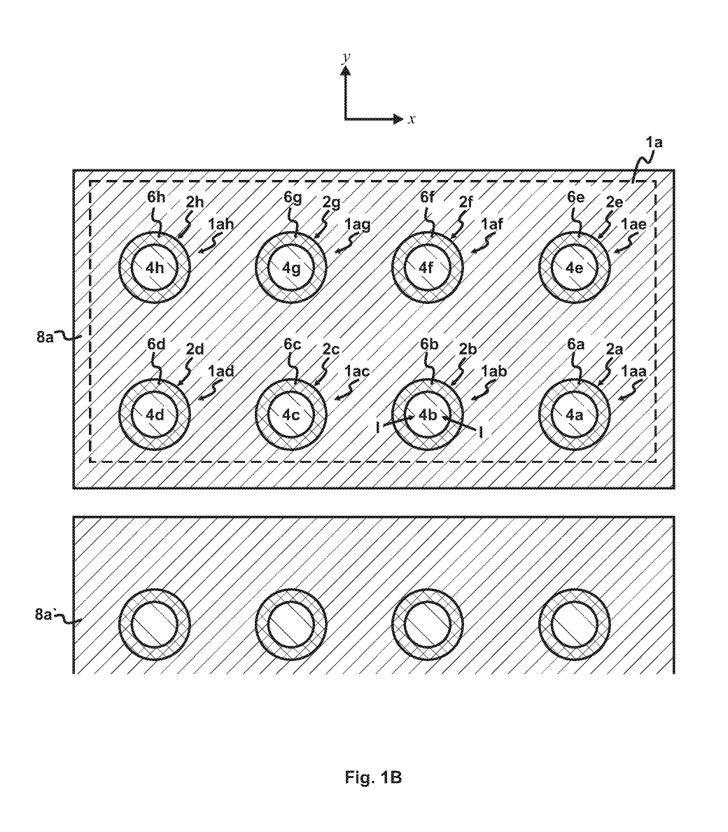

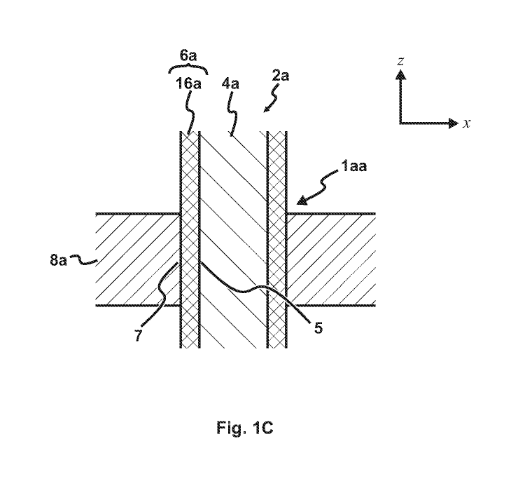

Referring now to FIG. 1A-1C, a first preferred three-dimensional vertical multiple-time-programmable memory (3D-MTP_{V}) comprising no separate diode layer is disclosed. It comprises a plurality of vertical MTP strings 1A, 1B . . . disposed side-by-side on the substrate circuit OK. Each MTP string (e.g. 1A) is vertical to the substrate 0 and comprises a plurality of vertically stacked MTP cells 1aa-1ha.

The preferred embodiment shown in this figure is an MTP array 10, which is a collection of all MTP cells sharing at least an address line. It comprises a plurality of vertically stacked horizontal address lines 8a-8h. After the memory holes 2a-2d penetrating these horizontal address lines 8a-8h are formed, the sidewalls of the memory holes 2a-2d are covered with memory layers 6a-6d. The remaining space in the memory holes 2a-2d is filled to form a plurality of vertical address lines 4a-4d.

FIG. 1B is its x-y cross-sectional view along the cutline AA′. Each of the horizontal address lines 8a, 8a′ is a conductive plate. The horizontal address line 8a is coupled with eight vertical address lines 4a-4h. Eight MTP cells 1aa-1ah are formed at the intersections of the horizontal address line 8a and the vertical address lines 4a-4h. All MTP cells 1aa-1ah coupled with a single horizontal address line 8a form an MTP-cell set 1a. Because the horizontal address line 8a is wide, it can be formed by a low-resolution photolithography (e.g. with feature size >60 nm).

To minimize the size of the memory holes, the memory layers 6a-6d comprises a re-programmable layer but no separate diode layer. As shown in FIG. 1C, the MTP cell 1aa comprises a horizontal address line 8a, a memory layer 6a on the sidewall of the memory hole 2a and a vertical address line 4a inside the memory hole 2a. The horizontal address line 8a comprises at least a first conductive material, which could be a metallic material or a heavily-doped semiconductor material. The memory layer 6a comprises at least a non-conductive material, which could be an insulating material or a lightly-doped semiconductor material. The vertical address line 4a comprises at least a second conductive material, which could be a metallic material or a heavily-doped semiconductor material.

The memory layer 6a comprises a re-programmable layer 16a but no separate diode layer. The re-programmable layer 16a generally comprises an insulating material, or a lightly-doped semiconductor material. Its resistance can be switched from low to high and vice versa. Exemplary re-programmable layers 16a include resistive RAM (RRAM) and phase-change memory (PCM) layers. RRAM and PCM are well known to those skilled in the art. RRAM has been actively researched lately. Its examples include NiO, TiO₂, SrTiO₃ and others. On the other hand, PCM has been used as the re-programmable layer in the 3D-XPoint product from Intel and Micron. Its examples include Ge₂Sb₂Te₅ (GST), AgInSbTe, GeTe—Sb₂Te₃ and others.

With no separate diode layer, the memory layer 6a could have a large reverse leakage current (i.e. its reverse current could be comparable to its forward current). To improve the rectifying ratio of the MTP cell 1aa, different address-line materials may be used. The following paragraphs disclose several preferred embodiments.

In a first preferred embodiment, the horizontal address lines 8a comprise a heavily-doped (e.g. P+ doped) semiconductor material, while the vertical address lines 4a comprise an oppositely-doped (e.g. N+ doped) semiconductor material. They form a built-in semiconductor diode, which can improve the rectifying ratio of the MTP cell 1aa. In a second preferred embodiment, the horizontal address lines 8a comprise a metallic material, while the vertical address lines 4a comprise a doped semiconductor material. They form a built-in Schottky diode, which can improve the rectifying ratio of the MTP cell 1aa. In a third preferred embodiment, the horizontal address lines 8a comprise a doped semiconductor material, while the vertical address lines 4a comprise a metallic material. They also form a built-in Schottky diode, which can improve the rectifying ratio of the MTP cell 1aa.

In a fourth preferred embodiment, the horizontal address line 8a comprises a first metallic material, whereas the vertical address line 4a comprises a second metallic material. To ensure a proper rectifying effect, different first and second metallic materials are used. For example, the rectifying ratio of the MTP cell is improved when the first and second metallic materials have different work functions. Alternatively, the rectifying ratio is improved when a first interface 7 between the first metallic material 8a and the memory layer 6a is different from a second interface 5 between the second metallic material 4a and the memory layer 6a.

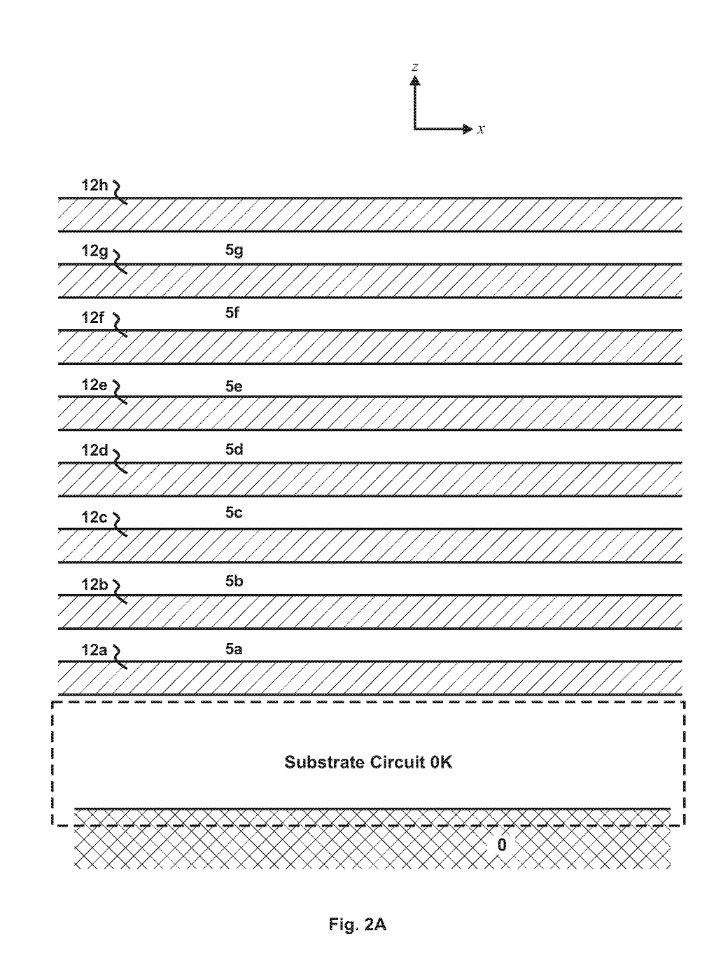

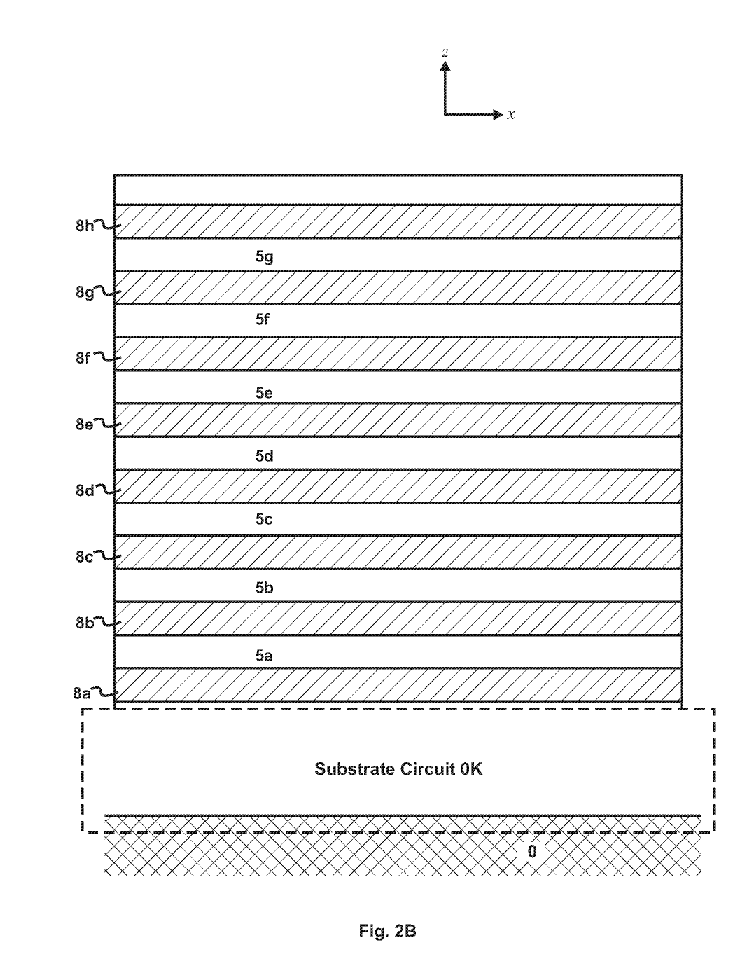

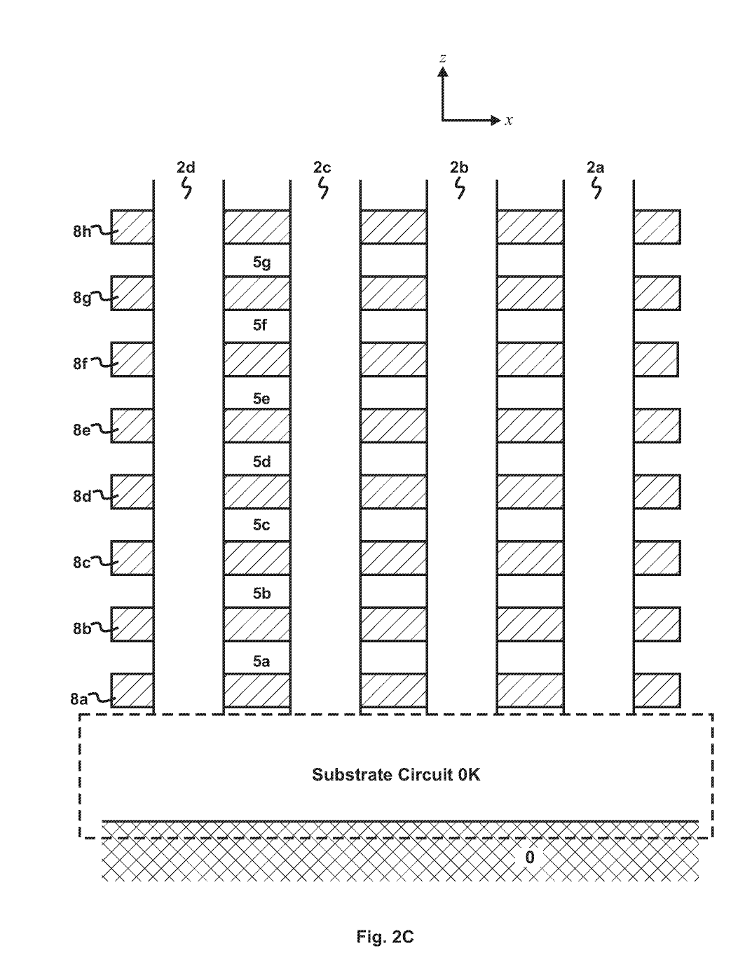

Referring now to FIGS. 2A-2C, three manufacturing steps for the preferred 3D-MTP_{V} are shown. First of all, first conductive layers 12a-12h are formed in continuously forming steps (FIG. 2A). To be more specific, after the substrate circuit OK (including transistors and the associated interconnects) are planarized, a first conductive layer 12a is formed. The first conductive layer 12a comprises a plain layer of first conductive material and has no patterns. Then a first insulating layer 5a is formed on the first conductive layer 12a. Similarly, the first insulating layer 5a has no patterns. Repeating the above process until alternate layers of the first conductive layers and the first insulating layers (a total of M layers) are formed. “Continuously forming steps” means that these forming steps (for the first conductive layer and the first insulating layer) are carried out continuously without any in-between pattern-transfer steps (including photolithography). This can ensure excellent planarization. As a result, the 3D-MTP_{V} comprising tens to hundreds of layers (e.g. 12a-12h) can be formed.

A first etching step is performed through all first conductive layers 12a-12h to form a stack of horizontal address lines 8a-8h (FIG. 2B). This is followed by a second etching step to form memory holes 2a-2d through all horizontal address lines 8a-8h (FIG. 2C). The sidewall of the memory holes 2a-2d is covered by memory layers 6a-6d before the remaining space in the memory holes 2a-2d are filled with at least a second conductive material to form the vertical address lines 4a-4d (FIG. 1A).

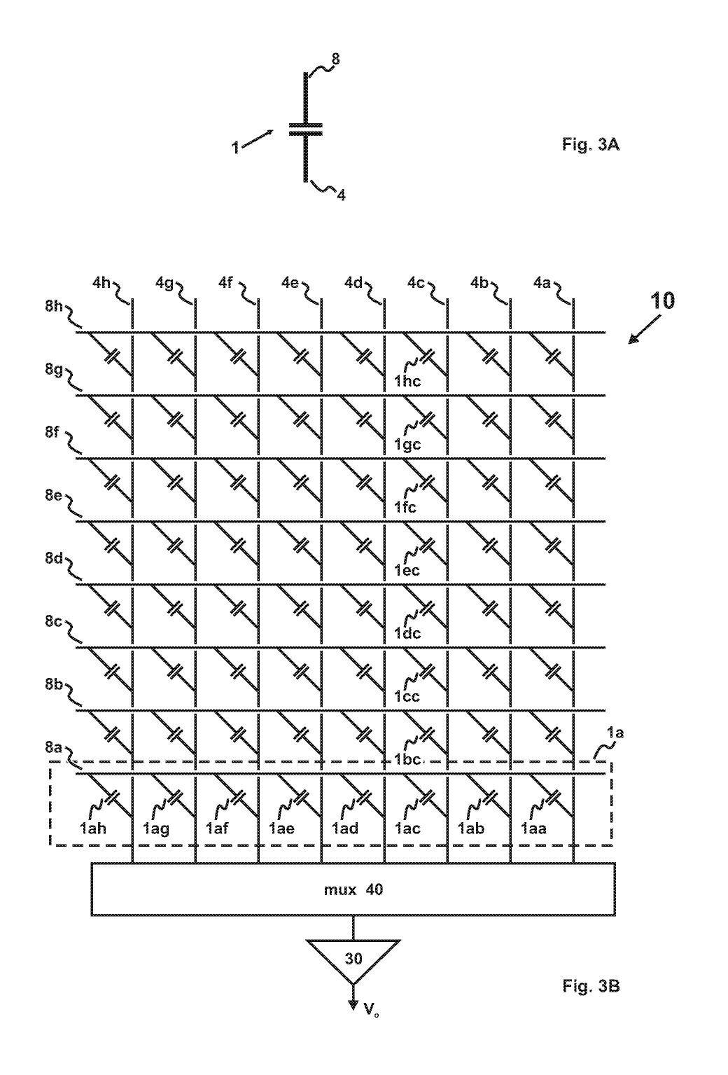

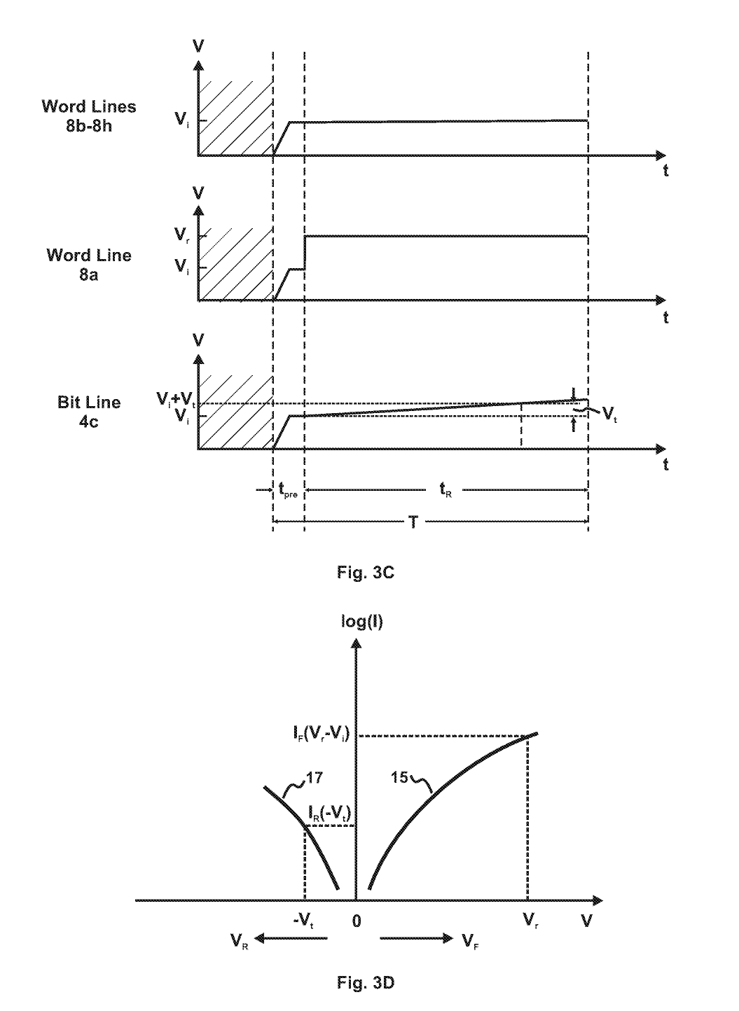

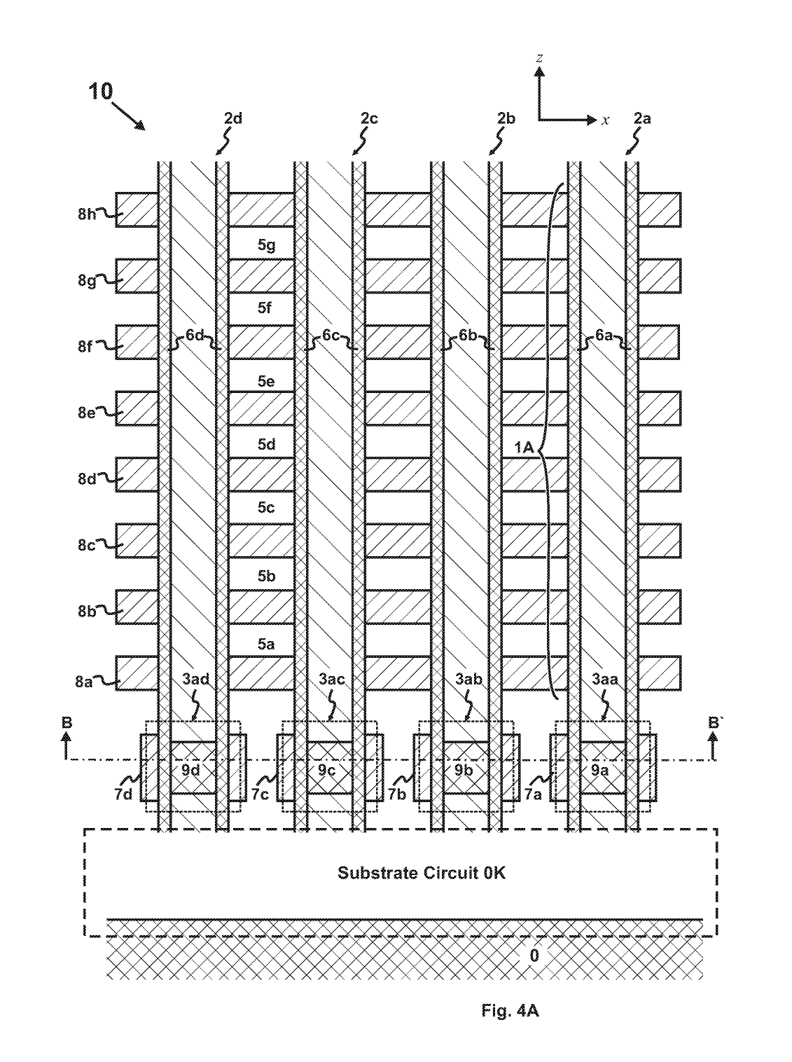

FIG. 3A is a symbol of the MTP cell 1. The MTP cell 1, located between a word line 8 and a bit line 4, comprises a re-programmable layer 12. As disclosed before, the resistance of the re-programmable layer 12 can be switched from high to low or vice versa. Note that, with no separate diode layer, the re-programmable layer 12 is leaky, i.e. its reverse current could be comparable to its forward current.

FIG. 3B is a circuit diagram of a first preferred read-out circuit for an MTP array 10. The MTP array 10 comprises a plurality of word lines 8a-8h, bit lines 4a-4h and MTP cells 1aa-1ah, 1bc-1hc. For the MTP array 10 to work properly, the I-V characteristic of the memory layer 6a needs to satisfy the following current requirement: the forward current I_{F} through a selected MTP cell (e.g. 1ac) should be substantially larger than the collective reverse current I_{R} through all unselected MTP cells (e.g. 1bc-1hc) on the same bit line (e.g. 4c). This can be expressed as I_{F}>>(n−1)*I_{R}, or, I_{R}<<I_{F}/(n−1), where n is the number of MTP cells on the bit line (e.g. 4c). As n typically has a large value (˜1000), I_{R} should be significantly smaller than I_{F}, i.e. I_{R}<<I_{F}/1000. When the above current requirement is met, the reverse (leakage) current I_{R} would not interfere with the read operation.

To satisfy the above current requirement, a small-V_{R} configuration is preferred. For the small-V_{R} configuration, the largest value of the reverse bias V_{R} on the MTP cells (e.g. 1bc-1hc) during read is substantially smaller than the smallest value of the forward bias V_{F} on the MTP cells (e.g. 1aa-1ah) during read, i.e. |V_{R}|<<V_{F}. Because the forward voltage V_{F} is comparable to the read voltage Vᵣ, the value of the reverse voltage V_{R} should be substantially smaller than the read voltage Vᵣ, i.e. |V_{R}|<<Vᵣ. This is substantially smaller than the conventional large-V_{R} configuration, where |V_{R}|˜Vᵣ.

To realize the small-V_{R} configuration, the MTP array 10 preferably comprises at least a sense amplifier 30. The sense amplifier 30 is coupled to bit lines 4a-4h through a multiplexor (mux) 40. The sense amplifier 30 toggles when the voltage change on the associated bit line 4a-4h reaches its threshold voltage Vₜ. Because the sense amplifier 30 has a large amplifying ratio, Vₜ is generally small (˜0.1V or smaller). This value is much smaller than Vᵣ (several volts), i.e. Vₜ<<Vᵣ. As a result, the bit lines 4a-4h have a small voltage swing during read.

In addition to the sense amplifier 30, a full-read mode also helps to realize the small-V_{R} configuration. For the preferred full-read mode, the data stored in all MTP cells on a selected word line are read out during a single read cycle. FIG. 3C is a signal timing diagram of the preferred full-read mode. The read cycle T includes two phases: a pre-charge phase tₚᵣₑ and a read-out phase t_{R}. During the pre-charge phase tₚᵣₑ, all address lines 8a-8h, 4a-4h in the MTP array 10 are pre-charged to a pre-determined initial voltage Vᵢ. This initial voltage Vᵢ could be an input bias voltage of the sense amplifier 30. During the read-out phase t_{R}, all bit lines 4a-4h are floating. The voltage on a selected word line (e.g. 8a) is raised to the read voltage Vᵣ, while voltage on other word lines 8b-8h remains at Vᵢ. Then the selected word line 8a starts to charge all bit lines 4a-4h through the MTP cells 1aa-1ah. As a result, the voltages on the bit lines 4a-4h begin to rise. The multiplexor 40 sends the voltage on each bit line (e.g. 4a) to the sense amplifier 30. When this voltage exceeds Vₜ, the output V_{O} is toggled and the data associated with the selected bit line is read out. At the end of the read cycle T, the data stored in all MTP cells 1aa-1ah on the word line 8a are read out.

FIG. 3D shows the current-voltage (I-V) characteristic of a preferred memory layer 6a. The small-V_{R} configuration can satisfy the above current requirement because the I-V characteristics of the memory layer 6a, which comprises at least a non-conductive material, have a logarithmic curve or a nearly logarithmic curve. In a worst scenario, the memory layer 6a (or, the re-programmable layer 16a) has no rectifying effect, i.e. it has symmetric forward I-V curve 15 and reverse I-V curve 17. Since V_{F} (˜Vᵣ, several volts)>>V_{R} (˜Vₜ, ˜0.1 V or smaller), the forward current I_{F} would be several orders of magnitude larger than the reverse current I_{R} because of the logarithmic I-V characteristics. Apparently, if the memory layer 6a (or, the re-programmable layer 16a) has certain rectifying effect, i.e. the forward I-V curve 15 is higher than the reverse I-V curve 17, the forward current I_{F} would be even larger than the reverse current I_{R} and therefore, it would be even easier to meet the above current requirement.

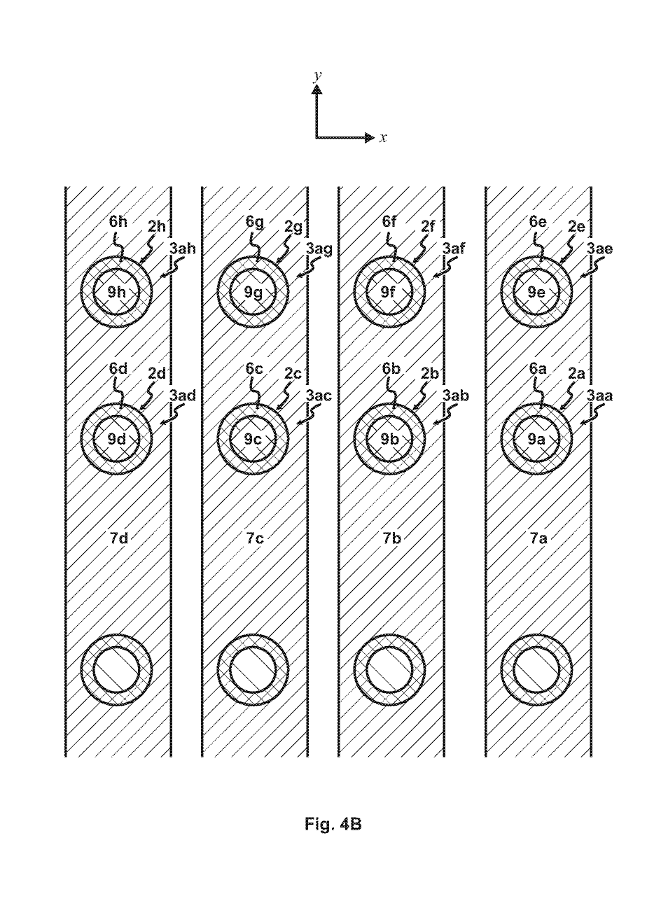

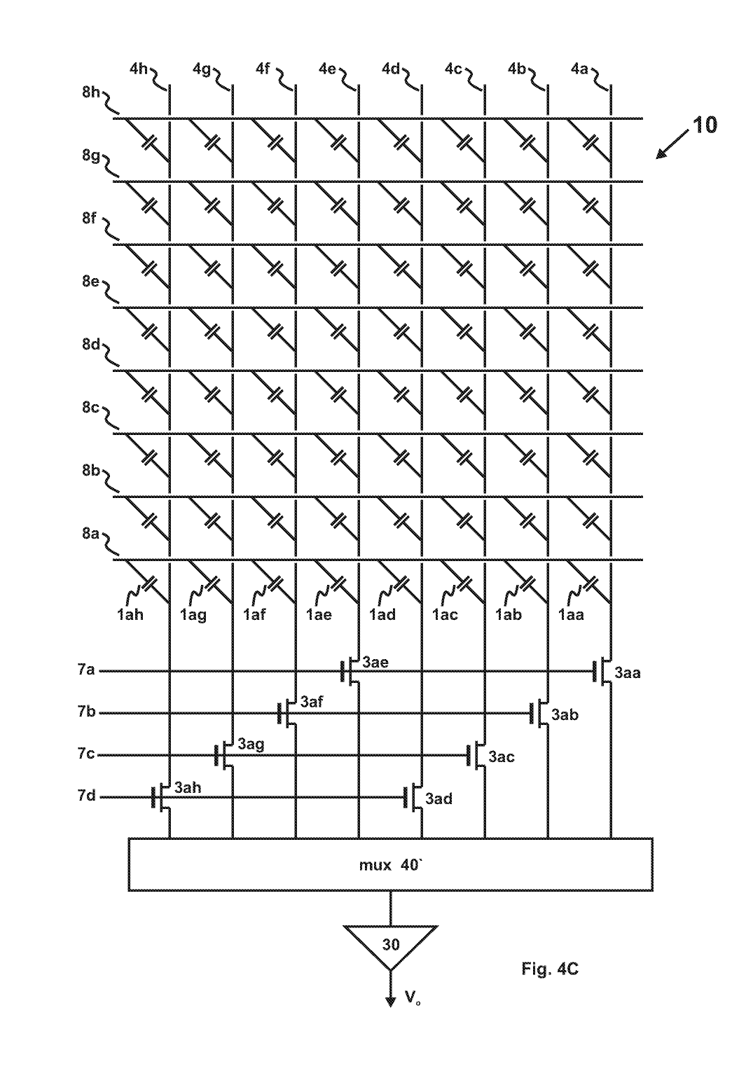

To facilitate address decoding, vertical transistors are formed in the memory holes. FIGS. 4A-4C disclose a second preferred MTP array 10 comprising vertical transistors 3aa-3ad. The vertical transistor 3aa is a pass transistor comprising a gate 7a, a gate dielectric 6a and a channel 9a (FIG. 4A). The channel 9a is formed in the semiconductor material filled in the memory hole 2a. Its doping could be same as, lighter than, or opposite to that of the vertical address line 4a. The gate 7a surrounds the memory holes 2a, 2e and controls the pass transistors 3aa, 3ae (FIG. 4B); the gate 7b surrounds the memory holes 2b, 2f and controls the pass transistors 3ab, 3af; the gate 7c surrounds the memory holes 2c, 2g and controls the pass transistors 3ac, 3ag; the gate 7d surrounds the memory holes 2e, 2h and controls the pass transistors 3ae, 3ah. The pass transistors 3aa-3ah form at least a decoding stage (FIG. 4C). In one preferred embodiment, when the voltage on the gate 7a is high while the voltages on the gates 7b-7d are low, only the pass transistors 3aa, 3ae are turned on, with other pass transistors off. The substrate multiplexor 40′ is a 2-to-1 multiplexor which selects a signal from the bit lines 4a, 4e. By forming vertical transistors 3aa-3d in the memory holes 2a-2d, the decoder design could be simplified.

While illustrative embodiments have been shown and described, it would be apparent to those skilled in the art that many more modifications than that have been mentioned above are possible without departing from the inventive concepts set forth therein. The invention, therefore, is not to be limited except in the spirit of the appended claims.

What is claimed is:

1. A three-dimensional vertical multiple-time-programmable memory (3D-MTP_{V}), comprising:
a semiconductor substrate comprising a substrate circuit;
a plurality of vertically stacked horizontal address lines above said semiconductor circuit;
a plurality of memory holes through said horizontal address lines;
a memory layer on the sidewalls of said memory holes and in contact with said horizontal address lines;
a plurality of vertical address lines in said memory holes and in contact with said memory layer;
a plurality of MTP cells at the intersections of said horizontal and vertical address lines;
wherein said memory layer comprises a re-programmable layer but no separate diode layer.

2. The 3D-MTP_{V} according to claim 1, wherein the largest value of the reverse bias (V_{R}) on said MTP cells during read is substantially smaller than the smallest value of the forward bias (V_{F}) on said MTP cells during read.

3. The 3D-MTP_{V} according to claim 1, further comprising:
at least a bit line associated with a selected one of said MTP cells; and
at least a sense amplifier coupling to said bit line.

4. The 3D-MTP_{V} according to claim 3, wherein the threshold voltage (Vₜ) of said sense amplifier is substantially smaller than the read voltage (Vᵣ).

5. The 3D-MTP_{V} according to claim 1, wherein:
said horizontal address lines comprise at least a first conductive material;
said memory layer comprises at least a non-conductive material; and
said vertical address lines comprise at least a second conductive material.

6. The 3D-MTP_{V} according to claim 5, wherein said memory layer comprises a re-programmable layer.

7. The 3D-MTP_{V} according to claim 6, wherein said re-programmable layer comprises a resistive RAM (RRAM) layer.

8. The 3D-MTP_{V} according to claim 6, wherein said re-programmable layer comprises a phase-change memory (PCM) layer.

9. The 3D-MTP_{V} according to claim 5, wherein said first and second conductive materials are different conductive materials.

10. The 3D-MTP_{V} according to claim 9, wherein said first conductive material is a doped semiconductor material, and said second conductive material is an oppositely-doped semiconductor material.

11. The 3D-MTP_{V} according to claim 9, wherein said first conductive material is a metallic material, and said second conductive material is a doped semiconductor material.

12. The 3D-MTP_{V} according to claim 9, wherein said first conductive material is a doped semiconductor material, and said second conductive material is a metallic material.

13. The 3D-MTP_{V} according to claim 9, wherein said first conductive material is a first metallic material, said second conductive material is a second metallic material, and said first and second metallic materials have different work functions.

14. The 3D-MTP_{V} according to claim 1, wherein said horizontal address lines have a first interface with said memory layer, said vertical address lines have a second interface with said memory layer, and said first and second interfaces are different interfaces.

15. The 3D-MTP_{V} according to claim 1, wherein the data stored in all MTP cells coupled to a selected one of said horizontal address lines are read out in a single read cycle.

16. The 3D-MTP_{V} according to claim 15, wherein both said horizontal address lines and said vertical address lines are pre-charged to an initial voltage (Vᵢ) during a pre-charge phase of said read cycle.

17. The 3D-MTP_{V} according to claim 16, wherein said vertical address lines are floating during a read-out phase of said read cycle.

18. The 3D-MTP_{V} according to claim 1, further comprising an MTP string including all MTP cells coupled to a selected vertical address line.

19. The 3D-MTP_{V} according to claim 18, further comprising a vertical transistor coupled to said MTP string.

20. The 3D-MTP_{V} according to claim 19, wherein said vertical transistor is formed in a first portion of said memory hole, and said MTP string is formed in a second portion of said memory hole.
